(19) United States
(12) Patent Application Publication
(10) Pub. No.: US 2010/0103758 A1
(43) Pub. Date: Apr. 29, 2010

(54) Semiconductor memory device having sense amplifier

(75) Inventors: Yoshiro Riho, Tokyo (JP); Shuichi Kubouchi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/588,730

(22) Filed: Oct. 26, 2009

(30) Foreign Application Priority Data
Oct. 27, 2008 (JP) 2008-275979

(51) Int. Cl. G11C 7/02; G11C 5/14

(52) U.S. Cl. 365/207; 365/226

(57) ABSTRACT

To provide a first power supply wiring that supplies a lower-side write potential to a sense amplifier, a second power supply wiring that supplies a higher-side write potential to the sense amplifier, a third power supply wiring that supplies an overdrive potential to the sense amplifier, and a stabilizing capacitance arranged between the first power supply wiring and the third power supply wiring. With this configuration, a capacitance value applied to the lower-side write potential and a capacitance value applied to the overdrive potential inevitably match, and thus fluctuation of the lower-side write potential and fluctuation of the overdrive potential at an initial stage of a sense operation are offset.

### BACKGROUND OF THE INVENTION

1. Field of the Invention

The present invention relates to a semiconductor memory device, and, more particularly relates to a semiconductor memory device that includes sense amplifiers.

2. Description of Related Art

In semiconductor memory devices such as a DRAM (Dynamic Random Access Memory), sense amplifiers that amplify a signal read from a memory cell to a bit line are employed. However, the signal read to the bit line is very weak, and thus amplification by the sense amplifiers takes a relatively longer period of time. This causes a problem that an access speed is rate-controlled during random access.

As a technique to improve sensing speed, an overdrive potential is used. See Japanese Patent Application Laid-open No. 2000-22108. This is a technique in which an overdrive potential higher than a higher-side write potential is supplied to a sense amplifier at an initial stage of a sense operation, thereby improving the sensing speed.

However, during a sense operation, a large number of sense amplifiers are simultaneously activated, and thus there is a problem that the overdrive potential is easily fluctuated. To solve such a problem, it is possible to adopt a method of increasing the size of a power supply circuit that produces the overdrive potential. However, this method is not preferable because its chip area is significantly increased.

Alternatively, it is also possible to adopt a method of using a stabilizing capacitance to stabilize the overdrive potential. However, to stabilize the overdrive potential by solely using a stabilizing capacitance, a very large capacitance is required to a stabilizing capacitor. Thus, the chip area is greatly increased also in this case. Further, at an initial stage of the sense operation, a lower-side write potential is fluctuated similarly to the overdrive potential, and thus, in order that a fluctuation amount of the lower-side write potential is set equal to that of the overdrive potential, it is necessary to add a stabilizing capacitance having the same capacitance value to the lower-side write potential. As a result, the chip area is further increased.

Such problems similarly occur not only in a sense amplifier in which an overdrive operation is performed, but also in a sense amplifier in which any overdrive operation is not performed. That is, even in a sense amplifier in which any overdrive operation is not performed, a large number of sense amplifiers are simultaneously activated during its sense operation. Thus, various drive potentials are easily fluctuated.

### SUMMARY

The present invention seeks to solve one or more of the above problems, or to improve upon those problems at least in part.

In one embodiment, there is provided a semiconductor memory device comprising: a sense amplifier that amplifies a potential difference appearing in a pair of bit lines; a first power supply wiring that supplies a first potential via a first driver to the sense amplifier; a second power supply wiring that supplies a second potential via a second driver to the sense amplifier; and a stabilizing capacitance arranged between the first power supply wiring and the second power supply wiring.

In the present invention, it is preferred that there is further provided a third power supply wiring that supplies a third potential via a third driver to the sense amplifier, the first potential is a lower-side write potential of the bit lines, the third potential is a higher-side write potential of the bit lines, and the second potential is an overdrive potential higher than the higher-side write potential.

According to the present invention, the stabilizing capacitance is arranged between the first and second potentials as drive potentials of the sense amplifier. Accordingly, it is not necessary to separately arrange the stabilizing capacitance to each of the potentials. Further, capacitance values applied to these potentials inevitably match, and thus fluctuation of the potential at an initial stage of a sense operation is offset. With this configuration, it becomes possible to effectively suppress fluctuation of a sense-amplifier drive potential while suppressing an increase in chip area to minimum.

Particularly, when the stabilizing capacitance is arranged between the first power supply wiring that supplies the lower-side write potential and the second power supply wiring that supplies the overdrive potential, it becomes possible to effectively suppress the fluctuation of the overdrive potential.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a circuit diagram showing main parts of a semiconductor memory device according to a preferred embodiment of the present invention;

FIG. 2 is a circuit diagram of a memory cell;

FIG. 3 is a circuit diagram of a sense amplifier;

FIG. 4 is a schematic cross-sectional view of a stabilizing capacitance configured by a trench gate capacitance;

FIG. 5 is a schematic cross-sectional view of a stabilizing capacitance configured by a planar gate capacitance;

FIG. 6 is a waveform chart showing an operation of the semiconductor memory device according to the embodiment;

FIG. 7 is an example of a layout of a VOD generator and the stabilizing capacitance on a chip;

FIG. 8 is another example of a layout of the VOD generator and the stabilizing capacitance on the chip;

FIG. 9 is still another example of a layout of the VOD generator and the stabilizing capacitance on the chip;

FIG. 10 is a schematic diagram showing an example of a wiring network of a power supply wiring that supplies the overdrive potential VOD;

FIG. 11 is a schematic diagram showing an example of the wiring network of the power supply wiring that supplies the lower-side write potential VSSA;

FIG. 12 is a schematic diagram of an example of arranging the power supply wirings adjacently on wiring layers; and

FIG. 13 is a circuit diagram showing main parts of a semiconductor memory device according to another embodiment of the present invention.

### DETAILED DESCRIPTION OF THE EMBODIMENTS

Preferred embodiments of the present invention will be explained below in detail with reference to the accompanying drawings.

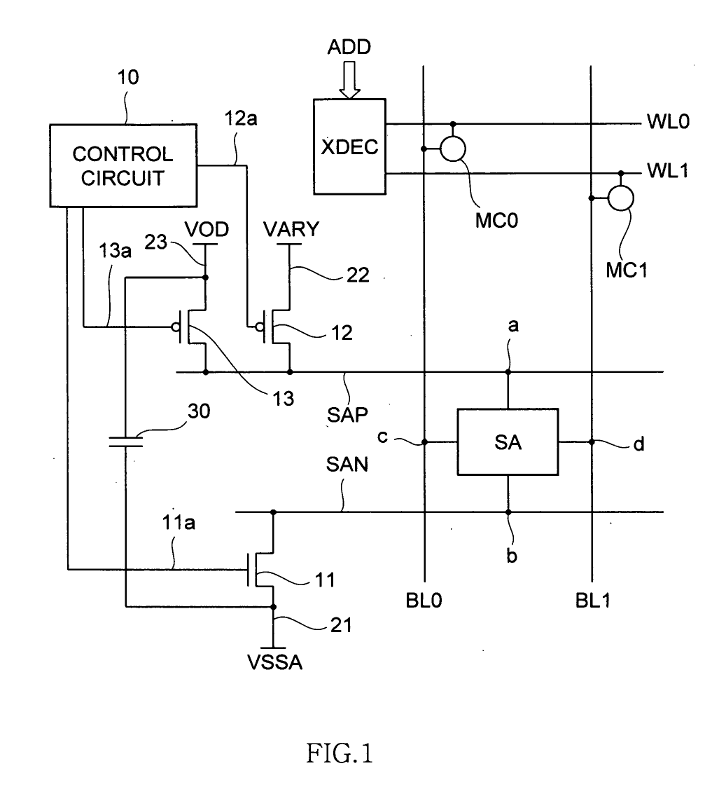

FIG. 1 is a circuit diagram showing main parts of a semiconductor memory device according to an embodiment of the present invention.

The semiconductor memory device according to the present embodiment is a DRAM. As shown in FIG. 1, memory cells MC0 and MC1 are disposed at an intersection between a bit line BL0 and a word line WL0, and at an intersection between a bit line BL1 and a word line WL1, respectively. The bit line BL0 and the bit line BL1 form a pair. One of the pair of the bit lines BL0 and BL1 is supplied with a higher-side write potential, and the other one is supplied with a lower-side write potential by a sense amplifier SA. Needless to mention, in practice, a large number of bit lines and word lines are arranged other than this pair, and memory cells are respectively positioned at corresponding intersections; however, these are omitted in FIG. 1.

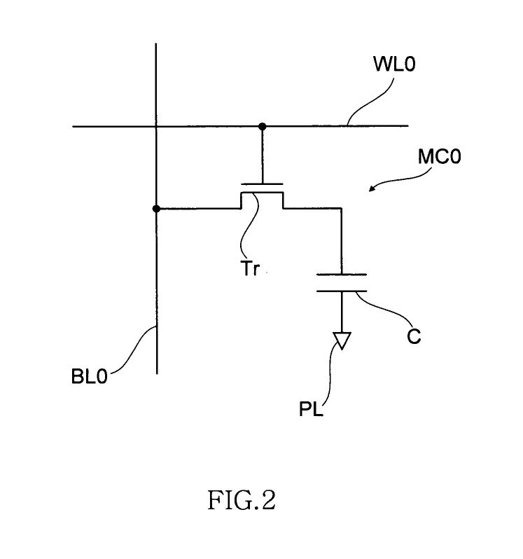

As shown in FIG. 2, the memory cell MC0 is configured by a cell transistor Tr and a cell capacitor C connected in series between the bit line BL0 and a plate wiring PL. A gate electrode of the cell transistor Tr is connected to the corresponding word line WL0. Thereby, when the word line WL0 is brought into an active high level, the corresponding cell transistor Tr is turned on, and as a result, the cell capacitor C is connected to the corresponding bit line BL0. Selection of the word line WL0 is performed by a row decoder XDEC shown in FIG. 1, and according to a value of a row address ADD, the predetermined word line WL0 is at a high level.

the higher-side write potential or the lower-side write potential is supplied to the cell capacitor C according to data to be stored when writing data in the memory cell MC0. As described later, in the present embodiment, the higher-side write potential is written as VARY, and is set to 1.2 V, for example. The lower-side write potential is written as VSSA, and is set to 0 V (ground potential), for example. Driving the bit lines BL0 and BL1 along with writing such data is performed by the sense amplifier SA.

On the other hand, when reading the data from the memory cell MC0, a bit line BL is precharged to an intermediate potential, i.e., (VARY−VSSA)/2 (such as 0.6 V. Hereinafter, “VBLP”), and thereafter, the cell transistor Tr is turned on. Thereby, when the higher-side write potential has been stored in the cell capacitor C, the potential of the bit line BL0 slightly rises from the intermediate potential VBLP. In contrast, when the lower-side write potential has been stored in the cell capacitor C, the potential of the bit line BL0 slightly falls from the intermediate potential VBLP. Thus, a very small potential difference thus occurring between the bit lines BL0 and BL1 is amplified by the sense amplifier SA.

As shown in FIG. 1, the sense amplifiers SA include four nodes a, b, c, and d. Among these nodes, the nodes a and b are power supply nodes, and connected to a higher-side-potential drive wiring SAP and a lower-side-potential drive wiring SAN, respectively. On the other hand, the nodes c and d are signal nodes, and connected to the bit lines BL0 and BL1, respectively.

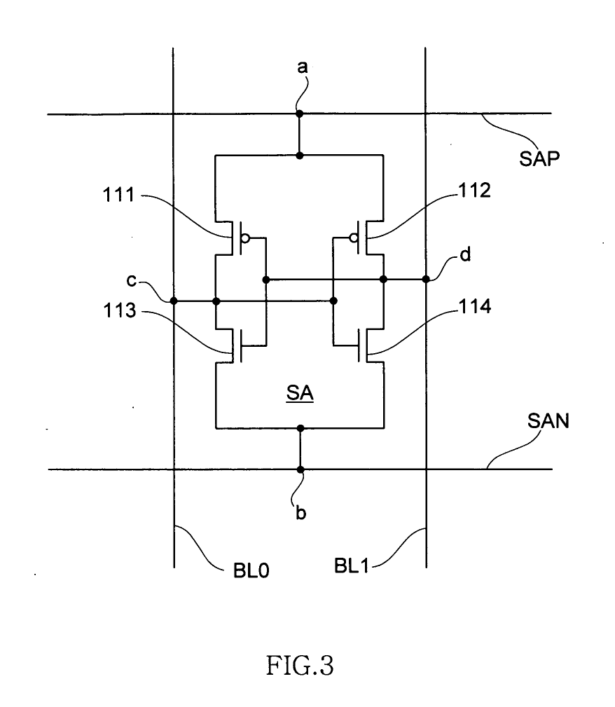

FIG. 3 is a circuit diagram of the sense amplifier SA.

As shown in FIG. 3, the sense amplifier SA is configured by P-channel MOS transistors 111 and 112 and N-channel MOS transistors 113 and 114. The P-channel MOS transistor 111 and the N-channel MOS transistor 113 are connected in series between the power supply node a and the power supply node b. The contact points thereof are connected to one signal node c, and the gate electrodes thereof are commonly connected to the other signal node d. Similarly, the P-channel MOS transistor 112 and the N-channel MOS transistor 114 are connected in series between the power supply node a and the power supply node b. The contact points thereof are connected to one signal node d and the gate electrodes thereof are commonly connected to the other signal node c.

By such a flip-flop structure, when the potential difference occurs in a bit line pair of BL0 and BL1 in a state that the higher-side-potential drive wiring SAP and the lower-side-potential drive wiring SAN are supplied with a predetermined potential, the potential of the higher-side-potential drive wiring SAP is supplied to one of the bit line pair, and the potential of the lower-side-potential drive wiring SAN is supplied to the other one of the bit line pair. As described later, in the present embodiment, the higher-side-potential drive wiring SAP is supplied with the higher-side write potential VARY, and the lower-side-potential drive wiring SAN is supplied with the lower-side write potential VSSA. Further, at an initial stage of the sense operation, the higher-side-potential drive wiring SAP is temporarily supplied with an overdrive potential VOD higher than the higher-side write potential VARY.

Referring back to FIG. 1, between the lower-side-potential drive wiring SAN and a power supply wiring 21, a driver 11 is connected. The power supply wiring 21 is supplied with the lower-side write potential VSSA. As a result, when the driver 11 is turned on, the lower-side-potential drive wiring SAN is supplied with the lower-side write potential VSSA. In the present embodiment, the driver 11 is configured by an N-channel MOS transistor. Accordingly, the driver 11 is turned on when a control signal 11a becomes a high level.

Between the higher-side-potential drive wiring SAP and a power supply wiring 22, a driver 12 is connected. The power supply wiring 22 is supplied with the higher-side write potential VARY. As a result, when the driver 12 is turned on, the higher-side-potential drive wiring SAP is supplied with the higher-side write potential VARY. In the present embodiment, the driver 12 is configured by a P-channel MOS transistor. Accordingly, the driver 12 is turned on when a control signal 12a becomes a low level.

Between the higher-side-potential drive wiring SAP and a power supply wiring 23, a driver 13 is connected. The power supply wiring 23 is supplied with the overdrive potential VOD. As a result, when the driver 13 is turned on, the higher-side-potential drive wiring SAP is supplied with the overdrive potential VOD. In the present embodiment, the driver 13 is configured by a P-channel MOS transistor. Accordingly, the driver 13 is turned on when a control signal 13a becomes a low level. The overdrive potential VOD is generated by a VOD generator described later, and its potential is set to 1.45 V, for example.

These control signals 11a to 13a are generated by a control circuit 10 shown in FIG. 1. Control timings of the drivers 11 to 13 by the control circuit 10 will be described later.

As shown in FIG. 1, between the power supply wiring 21 and the power supply wiring 23, a stabilizing capacitance 30 is connected. The stabilizing capacitance 30 serves a role of offsetting fluctuation of the lower-side write potential VSSA and that of the overdrive potential VOD at an initial stage of the sense operation. A capacitance value of the stabilizing capacitance 30 per each bank is designed to satisfy an equation of:

Cvod≧(VARY−VBLP)·Cb/(VOD−VARY) (1)

where Cb represents all capacitance values of bit lines simultaneously selected within a bank, and Cvod represents a capacitance value of the stabilizing capacitance 30 per each bank. When the equation (1) is satisfied, the fluctuation at an initial stage of the sense operation is almost completely offset.

The method of configuring the stabilizing capacitance 30 on a chip is not particularly limited. However, it is preferred to utilize a gate capacitance of an MOS transistor. The reason for this is that when the gate capacitance is used, it becomes possible to secure a large capacitance value with a relatively small area. It is particularly preferred to utilize a trench gate capacitance utilizing a trench formed on a semiconductor substrate.

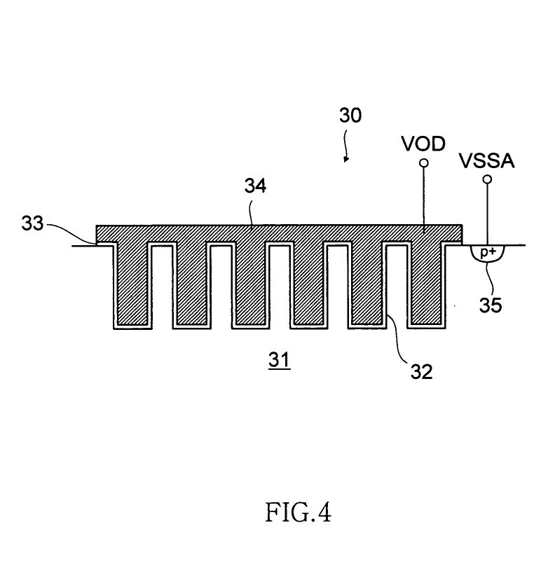

FIG. 4 is a schematic cross-sectional view of the stabilizing capacitance 30 configured by the trench gate capacitance. In an example shown in FIG. 4, a plurality of trench gates 32 are formed on a p-type semiconductor substrate 31, and inside each of the trench gates 32, a gate electrode 34 is buried via a gate dielectric film 33. When the lower-side write potential VSSA is supplied via a p⁺ region 35 to the p-type semiconductor substrate 31 and the overdrive potential VOD is supplied to the gate electrode 34, it becomes possible to form the stabilizing capacitance 30 having a large capacitance, with a smaller area.

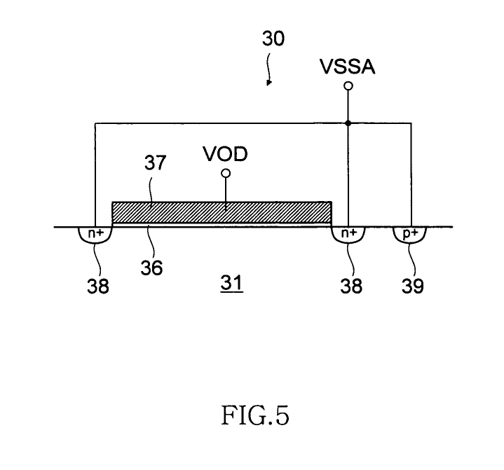

FIG. 5 is a schematic cross-sectional view of the stabilizing capacitance 30 configured by a planar gate capacitance. In an example shown in FIG. 5, a gate electrode 37 is formed on the p-type semiconductor substrate 31 via a gate dielectric film 36. On both sides of the p-type semiconductor substrate 31 below the gate electrode 37, n⁺ regions 38 as source/drain regions are arranged. However, these n⁺ regions 38 are fixed to the lower-side write potential VSSA, and thus do not function as a transistor in practice. When the lower-side write potential VSSA is supplied via a p⁺ region 39 to the p-type semiconductor substrate 31 and the overdrive potential VOD is supplied to the gate electrode 37, it becomes possible to form the planar stabilizing capacitance 30. Thus, when the stabilizing capacitance 30 is configured by the planar gate capacitance, a step of forming the trench gate on the p-type semiconductor substrate 31 becomes unnecessary.

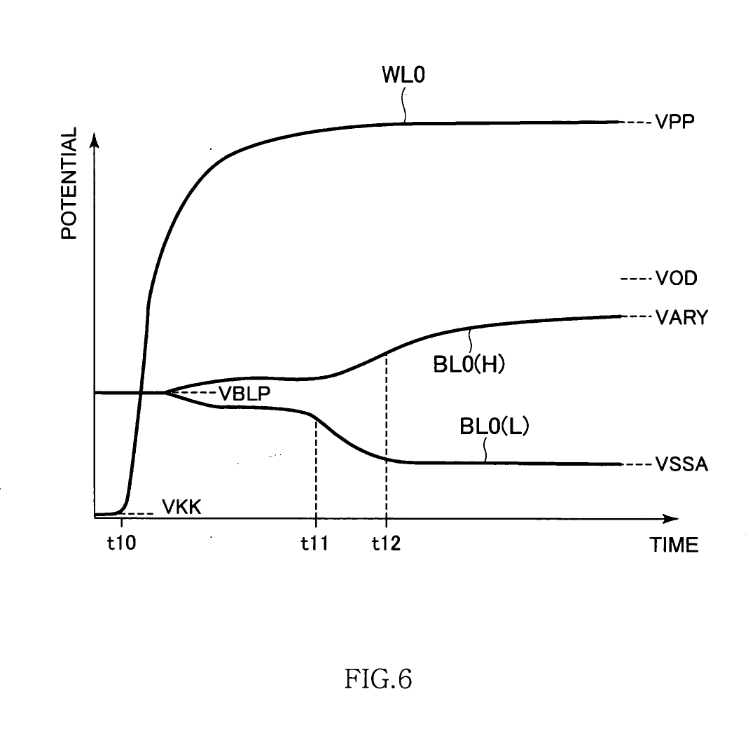

FIG. 6 is a waveform chart showing the operation of the semiconductor memory device according to the present embodiment.

First, before a time t10, the bit line pair of BL0 and BL1 are precharged to the intermediate potential VBLP. When the row address ADD reaches a predetermined value at the time t10, the word line WL0 corresponding thereto is ascended from a negative potential Vkk. A level of the activated word line WL0 is enhanced to a potential (VPP) much higher than the overdrive potential VOD. Thereby, the cell transistor Tr included in the memory cell MC is turned on, and thus the cell capacitor C and the bit line BL0 are short-circuited. As a result, the potential of the bit line BL0 is changed. Before the time t10, the control signals 11a to 13a are in an inactive state. Accordingly, all the drivers 11 to 13 are turned off.

Subsequently, when it is a time t11, the control circuit 10 activates the control signals 11a and 13a to a high level and a low level, respectively. Thereby, the drivers 11 and 13 are simultaneously turned on, and thus the lower-side write potential VSSA is supplied to the lower-side-potential drive wiring SAN, and the overdrive potential VOD is supplied to the higher-side-potential drive wiring SAP. In this case, the lower-side-potential drive wiring SAN and the higher-side-potential drive wiring SAP are connected with a large number of sense amplifiers SA, and thus, when the driver 11 is turned on, the power supply wiring 21 attempts to come up to a potential higher than the lower-side write potential VSSA, and when the driver 13 is turned on, the power supply wiring 23 attempts to fall down to a potential lower than the overdrive potential VOD.

However, such power supply fluctuation is suppressed by the stabilizing capacitance 30. That is, one electrode of the stabilizing capacitance 30 is connected to the power supply wiring 21 and the other electrode of the stabilizing capacitance 30 is connected to the power supply wiring 23, and thus, when the potentials of these power supply wirings 21 and 23 are fluctuated in a direction opposite to each other, the fluctuation is offset. As a result, in practice, substantially no fluctuation occurs. Particularly, when the capacitance value of the stabilizing capacitance 30 satisfies the equation (1), the fluctuation is substantially completely offset.

When the lower-side-potential drive wiring SAN and the higher-side-potential drive wiring SAP are thus driven, the sense amplifier SA lifts one of the bit line pair of BL0 and BL1 and lowers the other one. At this time, lifting one of the bit line pair of BL0 and BL1 is performed not by the higher-side write potential VARY but by the overdrive potential VOD higher in potential than the higher-side write potential VARY, and thus a faster sense operation is realized.

Subsequently, when it is a time t12, the control circuit 10 activates the control signal 12a to a low level so that the driver 12 is turned on, and inactivates the control signal 13a to a high level so that the driver 13 is turned off. Thereby, the higher-side write potential VARY is supplied to the higher-side-potential drive wiring SAP, and thus, one of the bit line pair of BL0 and BL1 is driven by the higher-side write potential VARY and the other one is driven by the lower-side write potential VSSA. Accordingly, data of the memory cell MC0 destructed by reading is restored.

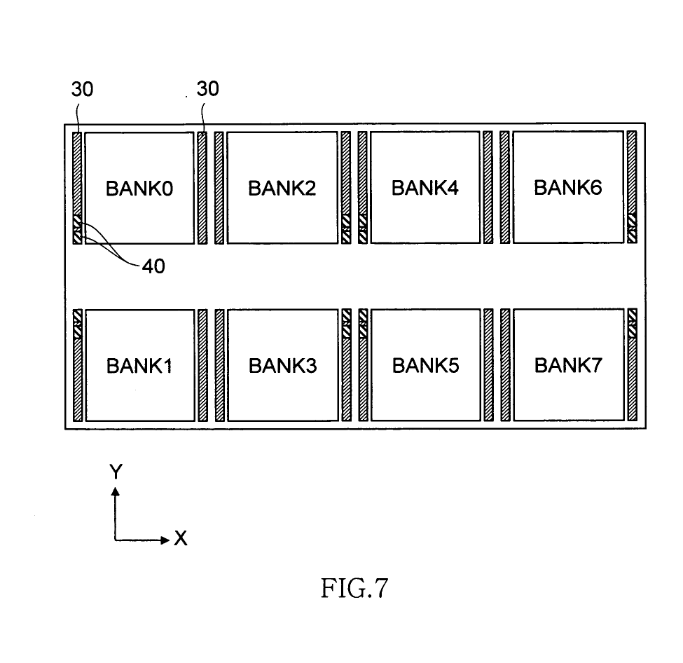

FIG. 7 is an example of a layout of a VOD generator 40 and the stabilizing capacitance 30 on a chip. In an example shown in FIG. 7, the memory cell array is divided into eight memory banks BANK0 to BANK7, and the stabilizing capacitance 30 is positioned opposite along a side of a Y direction of each memory bank. When the stabilizing capacitances 30 are positioned on both sides of each memory bank in this way, it becomes possible to obtain a higher stabilizing effect as compared to a case that the stabilizing capacitance 30 is positioned on a single side only. In an example shown in FIG. 7, two VOD generators 40 are assigned to each bank, and the two VOD generators 40 are collectively positioned at a substantial corner of the corresponding memory bank. When the VOD generators 40 are collectively positioned in this way, a layout design is facilitated.

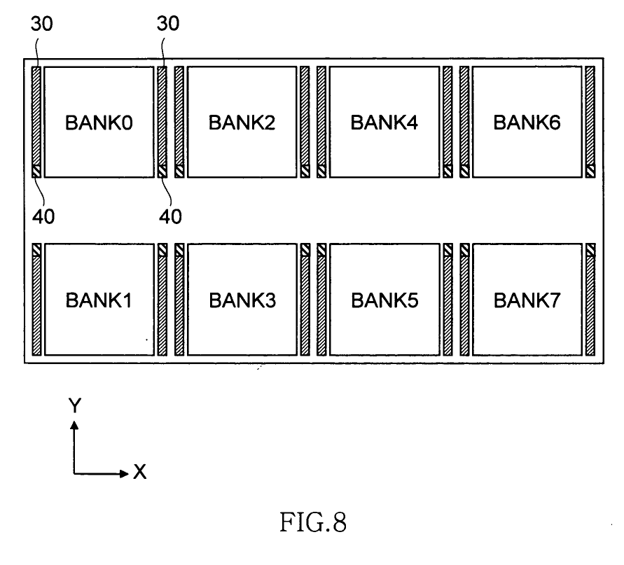

FIG. 8 is another example of a layout of the VOD generator 40 and the stabilizing capacitance 30 on the chip. An example shown in FIG. 8 differs from the layout shown in FIG. 7 in that two VOD generators 40 are positioned in a distributed manner. The other features are identical to those of the layout shown in FIG. 7. When the VOD generators 40 are thus positioned in a distributed manner, it becomes possible to effectively suppress a variation of the overdrive potential VOD within a wiring network. The wiring network will be described later.

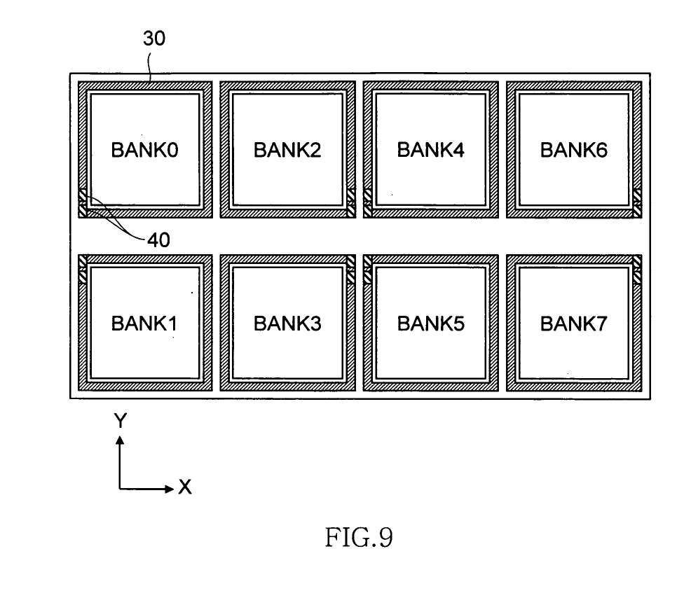

FIG. 9 is still another example of a layout of the VOD generator 40 and the stabilizing capacitance 30 on the chip. In an example shown in FIG. 9, the stabilizing capacitances 30 are positioned along sides of an X direction and a Y direction of each memory bank. That is, the stabilizing capacitances 30 are positioned to completely surround the corresponding memory bank. The other features are identical to those of the layout shown in FIG. 7. In this way, when the stabilizing capacitances 30 are positioned along the whole circumference of the memory bank, it becomes possible to achieve a much higher stabilizing effect.

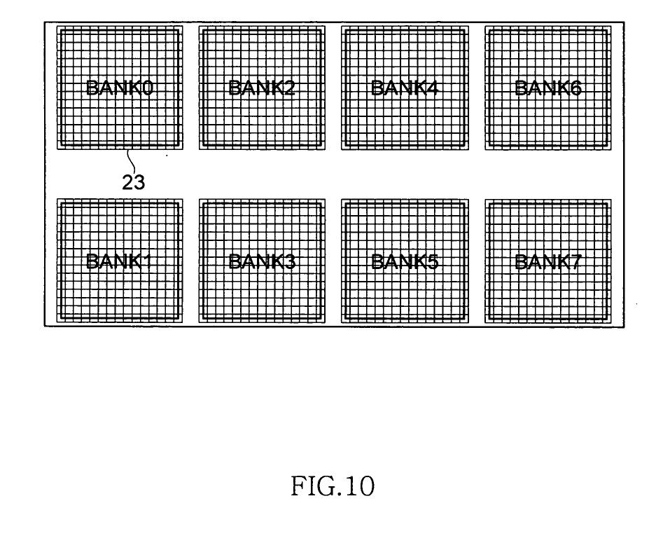

FIG. 10 is a schematic diagram showing an example of the wiring network of the power supply wiring 23 that supplies the overdrive potential VOD. In an example shown in FIG. 10, the wiring network of the power supply wiring 23 is routed all across like a mesh, and the wiring network is independent in each memory bank. In this way, when the wiring network of the power supply wiring 23 is rendered independent in each memory bank, designing the stabilizing capacitance 30 is facilitated.

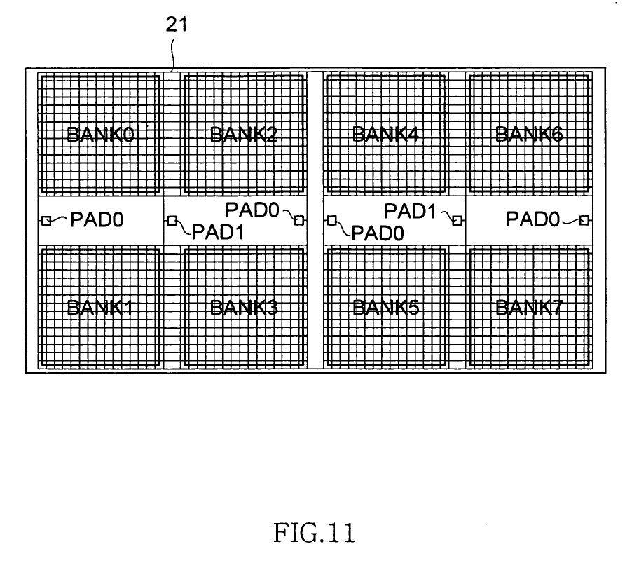

FIG. 11 is a schematic diagram showing an example of the wiring network of the power supply wiring 21 that supplies the lower-side write potential VSSA. In an example shown in FIG. 11, the wiring network of the power supply wiring 21 is routed all across like a mesh, and the wiring network is short-circuited between the memory banks. In an example shown in FIG. 11, a total of six external terminals PAD0 and PAD1 to which the lower-side write potential VSSA is supplied are positioned between even-numbered banks and odd-numbered banks. Among these external terminals, the external terminal PAD0 is shared between the upper and lower banks, and the external terminal PAD1 is shared between the upper and lower banks and left and right banks. In this way, when the wiring network of the power supply wiring 21 is short-circuited between the memory banks, it becomes possible to stabilize the lower-side write potential VSSA.

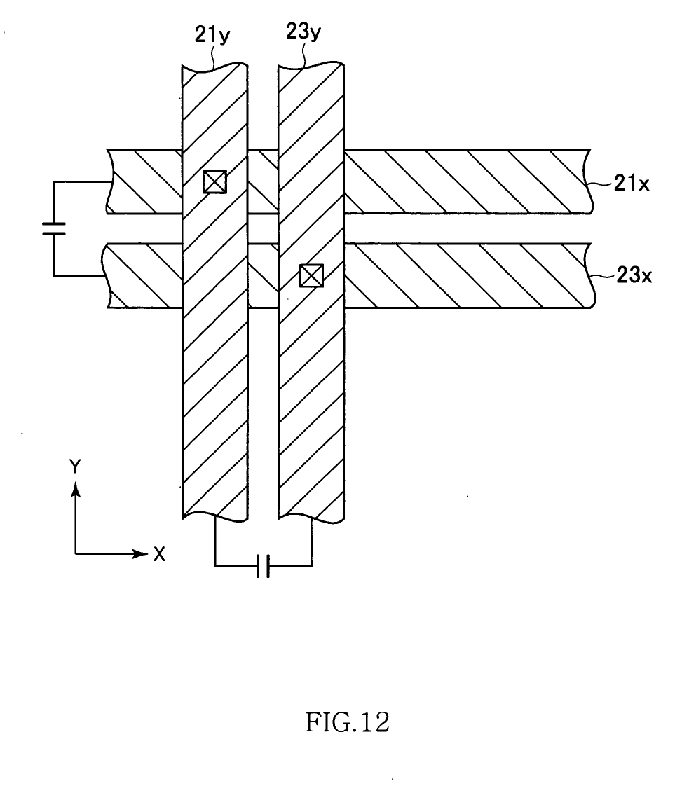

It is preferred that in the wiring network shown in FIGS. 10 and 11, a portion extending in an X direction and a portion extending in a Y direction be formed in different wiring layers. In this case, as shown in FIG. 12, when portions 21x and 23x extending in an X direction, out of the power supply wirings 21 and 23, are positioned adjacently and portions 21y and 23y extending in a Y direction, out of the power supply wirings 21 and 23, are positioned adjacently, the capacitance is added between the both even within the wiring network. Thus, it becomes possible to downsize the stabilizing capacitance 30.

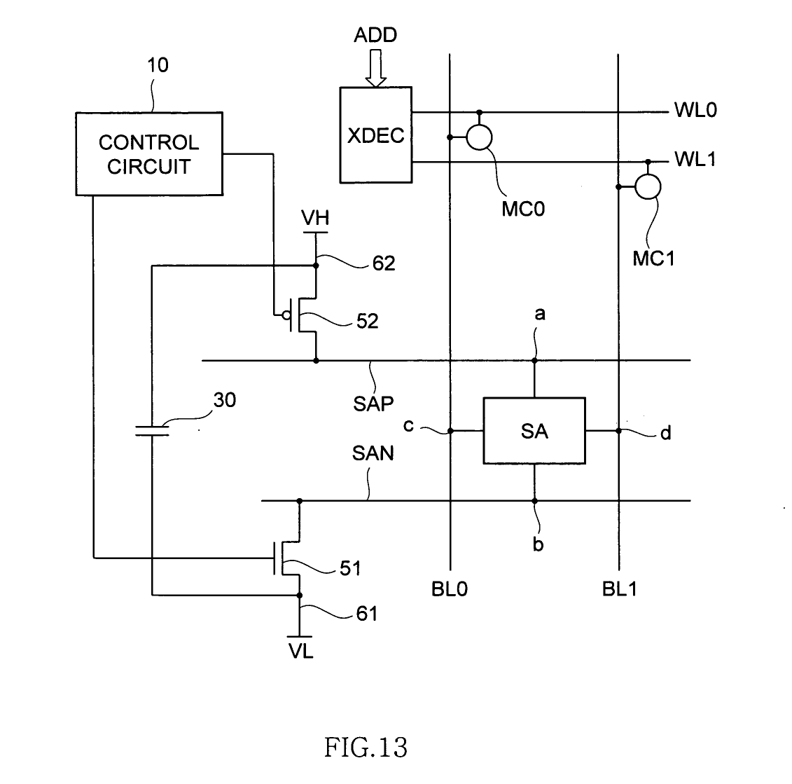

FIG. 13 is a circuit diagram showing main parts of a semiconductor memory device according to another embodiment of the present invention. Constituent elements identical to those of the embodiment shown in FIG. 1 are denoted by like reference numerals.

The present embodiment provides a semiconductor memory device as an example in which the sense amplifier does not perform any overdrive operation. A driver 51 is connected between the lower-side-potential drive wiring SAN and a power supply wiring 61, and a driver 52 is connected between the higher-side-potential drive wiring SAP and a power supply wiring 62. The power supply wiring 61 is supplied with a lower-side write potential VL, and the power supply wiring 62 is supplied with a higher-side write potential VH. In this case, the potentials VH and VL can optionally be an internal power supply produced inside the semiconductor memory device, or an external power supply supplied from outside the semiconductor memory device.

Also in the present embodiment, between the power supply wiring 61 and the power supply wiring 62, the stabilizing capacitance 30 is connected. Thereby, when the drivers 51 are simultaneously turned on to activate the sense amplifier SA, the fluctuation of the lower-side write potential VL and the fluctuation of the higher-side write potential VH are offset by the stabilizing capacitance 30. In this way, it is also possible to apply the present invention to a semiconductor memory device using a sense amplifier that does not perform any overdrive operation.

While preferred embodiments of the present invention have been described above, the invention is not limited to the above embodiments. Various modifications can be made without departing from the scope of the present invention, and needless to mention, these modifications are also included within the scope of the invention.

What is claimed is:

1. A semiconductor memory device comprising:
a sense amplifier that amplifies a potential difference appearing in a pair of bit lines;
a first power supply wiring that supplies a first potential via a first driver to the sense amplifier;
a second power supply wiring that supplies a second potential via a second driver to the sense amplifier; and
a stabilizing capacitance arranged between the first power supply wiring and the second power supply wiring.

2. The semiconductor memory device as claimed in claim 1, further comprising a third power supply wiring that supplies a third potential via a third driver to the sense amplifier, wherein
the first potential is a lower-side write potential of the bit lines, the third potential is a higher-side write potential of the bit lines, and the second potential is an overdrive potential higher than the higher-side write potential.

3. The semiconductor memory device as claimed in claim 2, further comprising a control circuit that simultaneously turns on the first and second drivers, and thereafter turns on the third driver.

4. The semiconductor memory device as claimed in claim 1, wherein the stabilizing capacitance is formed of a trench gate capacitance formed on a semiconductor substrate.

5. The semiconductor memory device as claimed in claim 1, wherein
the first and second power supply wirings have a wiring network in a mesh formed on a corresponding memory bank, and
the stabilizing capacitance is positioned at least along a first side of the memory bank and a second side parallel to the first side.

6. The semiconductor memory device as claimed in claim 2, wherein
Cvod≧(VARY−VBLP)·Cb/(VOD−VARY)
is satisfied where VARY represents the higher-side write potential, VBLP represents an intermediate potential between the lower-side write potential and the higher-side write potential, VOD represents the overdrive potential, Cb represents all capacitance values of the bit lines simultaneously selected within the bank, and Cvod represents a capacitance value of a stabilizing capacitance per each bank.
